(19) United States
(12) Patent Application Publication
(10) Pub. No.: US 2024/0183053 A1
(43) Pub. Date: Jun. 6, 2024

(54) APPARATUS AND METHOD FOR MANUFACTURING MAGNETIZABLE COMPONENTS CONSISTING OF CONCENTRICALLY LAYERED MATERIALS GROWN USING PATTERNED SUBSTRATE SEED TEMPLATES

(71) Applicant: Weinberg Medical Physics, Inc., North Bethesda, MD (US)

(72) Inventors: Irving N. WEINBERG, Chevy Chase, MD (US); Lamar Odell MAIR, Baltimore, MD (US)

(21) Appl. No.: 18/526,271

(22) Filed: Dec. 1, 2023

Related U.S. Application Data
(60) Provisional application No. 63/429,201, filed on Dec. 1, 2022.

(51) Int. Cl. C25D 5/48; C25D 3/20; C25D 5/02

(52) U.S. Cl. CPC C25D 5/48; C25D 3/20; C25D 5/02; H01L 28/40

(57) ABSTRACT

Methods and systems are provided for patterning surfaces, generating templates from the patterned surfaces, then using those templates to manufacture magnetizable components with micro- or nanoscale control over the physical properties of the component.

### CROSS-REFERENCE AND PRIORITY CLAIM

This application claims priority to U.S. Provisional Patent Application Ser. No. 63/429,201, entitled “APPARATUS AND METHOD FOR MANUFACTURING MAGNETIZABLE COMPONENTS CONSISTING OF CONCENTRICALLY LAYERED MATERIALS GROWN USING PATTERNED SUBSTRATE SEED TEMPLATES” filed Dec. 1, 2022, the entirety of which is incorporated by reference.

### FIELD

A method and apparatus for manufacturing magnetizable components using methods of patterning and material deposition. Disclosed embodiments may be used to manufacture components as small as 1 micrometer to as large as 1 meter.

### BACKGROUND

It is known that micro- and nanoscale structuring in magnetizable components can provide the component with unique physical properties, including unique saturation magnetization, Curie temperatures, and remanent magnetizations.

It is also known that micro- and nanoscale patterning of surfaces can increase surface area of a material by several orders of magnitude.

Previous work in the field of patterning has used two photon manufacturing approaches to generate high aspect ratio three dimensional patterns in polymers. These patterns can be subsequently processed to generate components with an array of shapes, sizes, and physical properties.

### SUMMARY

An apparatus and method for manufacturing magnetizable materials utilizing substrates patterned with columnar arrays in combination with sequential electroplating and vacuum chamber-based deposition techniques.

Disclosed embodiments describe the design and use of a system for patterning surfaces, generating templates from the patterned surfaces, then using those templates to manufacture magnetizable components with micro- or nanoscale control over the physical properties of the component.

### BRIEF DESCRIPTION OF THE FIGURES

FIG. 1 illustrates an embodiment of the disclosed method;

FIG. 2 shows a flowchart of a method of manufacture according to the disclosed embodiments; and

FIG. 3 shows an embodiment of an apparatus according to the disclosed embodiments.

### DETAILED DESCRIPTION

Disclosed embodiments refer to Weinberg et al., U.S. Ser. No. 17/860,426 entitled “Apparatus and Method for Automated Manufacturing of Structures with Electrically Conductive Segments”, that describe how to use electrodeposition to grow materials that are incorporated into a component, and how to engineer those materials during growth to provide the component with desired physical properties.

Disclosed embodiments describe an apparatus and method utilizing an ordered array of columnar structures composed of an electrically conductive material attached to an electrically conductive substrate. For the purposes of this specification, the ordered array of columnar structures may be fabricated using two photon polymerization (2PP) to first form an ordered array of holes in a two photon polymerization resist.

It is understood that the ordered array of holes may be made using techniques other than two photon polymerization, including techniques such as 3D printing, photolithography, or microscale milling techniques.

It is understood that the term “electrically conductive material” may mean a metallic material that has electrical conductivity greater than 1×10⁶ siemens per meter (S/m), or a conducting polymer having conductivity greater than 1×10⁴ siemens per meter.

The disclosed embodiments include an apparatus and method for making and modifying columnar structures. In one embodiment of the invention, columnar structures may be modified using sequentially grown concentric layers of material around the columnar structures via electrodeposition, followed by vapor phase deposition or implantation techniques. In one embodiment of the invention, the columnar structures are made of iron, and the vapor phase deposition or implantation consists of nitriding the iron to arrive at iron compositions of Fe₁₆N₂.

In some embodiments the growing proceeds until the entire surface of the substrate is filled with electrically conductive material.

In some embodiments, the apparatus for performing the method of the invention includes a vacuum chamber in which the substrate is placed after patterning. In some embodiments, an electrodeposition chamber inside the vacuum chamber allows a user to grown layers in a controlled gas environment, and also allows the user to alternate between electrochemical deposition and vapor phase deposition or implantation methods. In some embodiments, this alternating manufacturing process is used to completely fill the area over the substrate with iron nitride. It is understood that the electrodeposited and vapor deposited or vapor implanted materials may eventually be removed from the electrically conductive substrate for use in devices. It is understood that the component, or sample, may be thermally treated while still on the substrate, or after being removed from the substrate.

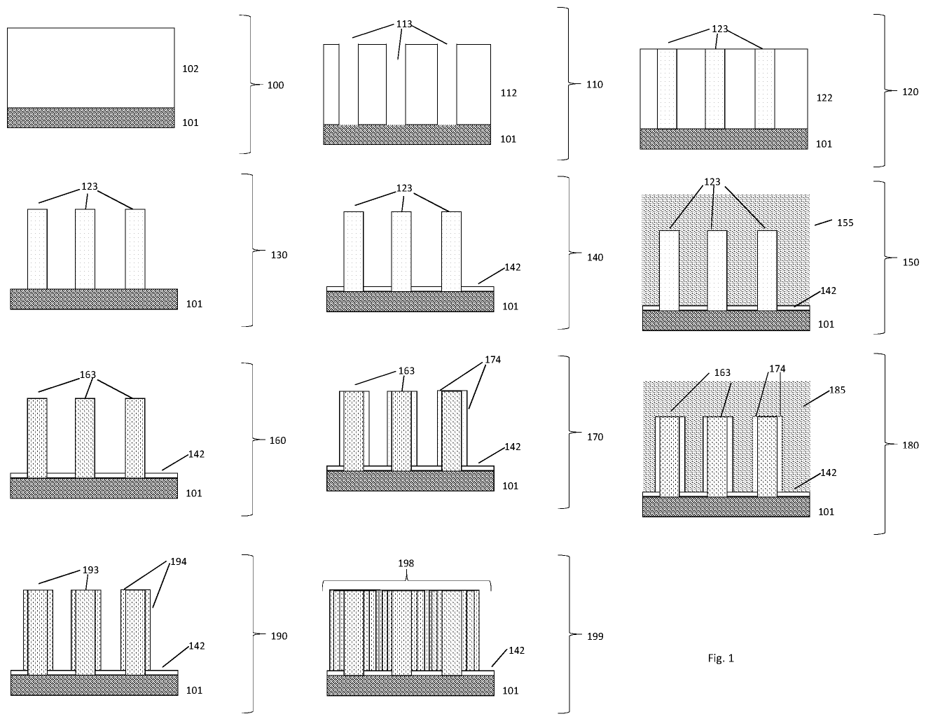

Referring to the figures, FIG. 1 shows an embodiment of the disclosed method. Panel 100 shows a substrate 101 having a modifiable resist 102 coated on one surface of the substrate 101. In some embodiments, the modifiable resist is 1 cm in height, and composed of a two photon polymerization positive resist. After exposure and development, the exposed region is removed. In one embodiment of the invention, a negative resist may be used. In one embodiment of the invention, other types of resist that do not rely on two photon polymerization may be used.

Panel 110 illustrates development of the resist 112, via removal of portions of the resist, to form holes 113 that travel through the thickness of the resist and expose the substrate 101. Development of the resist 112 so as to expose the substrate 101 is critical, as the substrate 101 serves as the surface for electrodeposition of electrically conductive material for subsequent processing steps.

Panel 120 shows the process of growing electrically conductive columns 123 in the holes 113. In some embodiments, the conductive columns 123 are grown via electrodeposition of iron.

Panel 130 shows removal of unmodified resist, leaving conducting columns 123 standing vertically from the substrate 101. In some embodiments, these columns are 1 centimeter tall and are arrayed in a two-dimensional hexagonal close packed lattice in which each conducting column has six nearest neighbor columns. In some embodiments, the columns are approximately 10 micrometers in diameter and are spaced approximately 100 micrometers apart.

Panel 140 shows deposition of a thin electrically insulating material 142 onto the substrate 101. In some embodiments, this electrically insulating material 142 may be a polymer resist. When applied, the electrically insulating layer blocks the surface of the substrate 101 from receiving materials deposited from electrodeposition procedures. In some embodiments, this layer 142 is not included in the method.

Panel 150 shows vacuum chamber deposition or implantation of a material using a vapor 155. Specifically, panel 150 shows the substrate 101 and conductive columns 123 in a vapor for physical vapor deposition or elemental implantation of some element into the conductive column 153 materials. In some embodiments, the conductive columns are composed of iron and the vapor is used to implant nitride into the iron for the formation of Fe₁₆N₂.

Panel 160 shows modified column structures 163 after being exposed to the vapor 155. In some embodiments, columns 163 are now composed of Fe₁₆N₂ after iron deposition and nitriding steps.

Panel 170 shows deposition of an electrically conducting material layers 174 onto the modified column structures 163. In some embodiments, the electrically conducting material layers 174 are composed of iron and are created by electrodeposition. It is understood that the conducting material layers may be generated by a means other than electrodeposition, and may be composed of metals, conductive polymers, or composites of metals and conductive polymers. It is understood that following this operation the deposited materials may be annealed to arrive at specific material phases or compositions.

Panel 180 shows repeated vacuum chamber deposition of implantation of a material using a vapor 185. A background vapor 185 is applied to modify the recently deposited conducting layer 174 that was grown around the conductive columns 163.

Panel 190 shows modified electrically conducting material layer 194. Panel 190 depicts conducting columns 193 and deposited layers 194 as being the same material after the vapor deposition or implantation procedure depicted in panel 180. It is understood that the materials shown in conducting columns 193 and deposited layers 194 may be similar or dissimilar.

Panel 199 shows layerings 198 that completely cover the space atop the thin insulating layer 142, completing the growth process. It is understood that the process may be ended prior to completely filling the available space on the surface layer 142.

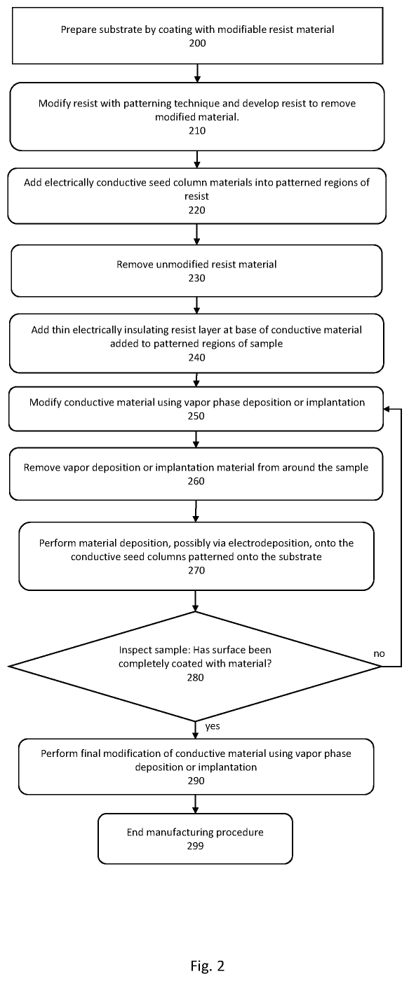

FIG. 2 shows a method of manufacturing. In operation 200, the method begins by preparing a substrate and coating the substrate with a modifiable resist material. It is understood that prior to adding the modifiable resist to the substrate may need to be cleaned.

The resist is modified with a patterning technique. The patterning technique may pattern the resist using photons, acoustic fields, magnetic fields, or electric fields. Following patterning, the resist is developed. Importantly, the development procedure exposes some part of the conductive substrate to the environment by removing modified resist material such that when the sample, or component, is surrounded by an electrolyte, that electrolyte comes into contact with the conducting substrate. The electrically conductive columns are grown on the conductive substrate 220 by adding electrically conductive material into the patterned regions of the resist. Unmodified resist material is removed 230, leaving behind only the electrically conductive column structures grown in operation 220. A thin electrically insulating layer may be added to the substrate in operation 240. Conductive column structures are modified using vapor phase deposition or implantation 250. The vapor phase deposition material is is removed around the sample 260. Electrically conducting seed columns patterned on the substrate are coated concentrically with a conductive material 270. It is understood that the coating may be performed via electroplating. Sample is inspected 280. Samples, which have open spaces on the surface of the material, receive further treatments starting back at operation 250. If the available surface has been completely filled with material, then the process proceeds to operation 290. In operation 290, a final modification of the deposited materials is performed using vapor phase deposition or implantation. In operation 299 the manufacturing procedure ends and the user can recover the sample.

It is understood that the entirety of the processing in the manufacturing process may occur in a vacuum chamber. It is understood that only the vapor phase deposition or implantation is performed in vacuum, and the other processing steps are performed at 1 atmosphere. It is understood that, for processes taking place entirely in a vacuum chamber, the electrodeposition processes may be performed with a background inert gas environment.

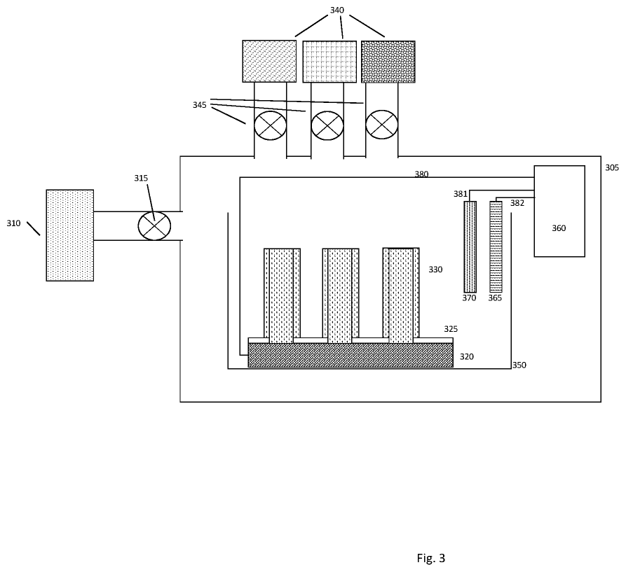

An apparatus for creating the samples is shown in FIG. 3. A vacuum chamber 305 is illustrated having a pump 310 for evacuating the chamber as well as a pump gate 31 for opening and closing the chamber to pumping pressures houses an electrodeposition chamber 350. The electrodeposition chamber 350 may be filled with fluid, filled with air or another gas, or evacuated. The electrodeposition chamber 350 contains an electrically conducting substrate 320 on which is grown conductive materials 330. The electrically conducting substrate 320 may have on its surface an electrically insulating coating 325. The vacuum chamber 305 may also contain a potentiostat 360 connected to a counter electrode 365 and a reference electrode 370 via electrical wires 381 and 382. The electrically conducting substrate 320 may act as a working electrode for electrodeposition and be connected to the potentiostat 360 by an electrically conducting wire 380. The chamber may have attached to it vapor reservoirs 340 that are connected to the vacuum chamber via gates 345 that can be opened and closed to control the vapor pressure in the vacuum chamber 305. The vapor reservoirs 345 may be opened one at a time, or in various combinations. Additionally, the vapor reservoirs may contain air or inert gases such as argon. In some embodiments, at least one of the vapor reservoirs 345 contains nitrogen. In some embodiments, the grown conductive materials 330 may be iron, which is nitrided after grown via opening of a vapor reservoir 345 containing nitrogen.

It is understood that the method and apparatus may also be used to manufacture capacitors. Capacitors are layers of conductors separated by insulating materials. In some embodiments, capacitors may be created by creating concentric layers around conductive columns. In some embodiments, the materials of the concentric layers are composed of dissimilar materials. By growing concentric layers of dissimilar materials and then etching one of the materials, it is understood that the process may be used to generate a concentric rings that are separated by air after the chemical or physical removal of the sacrificial material layer. In some embodiments, the empty space left behind after etching the sacrificial material may be filled with insulating materials. In some embodiments, the insulating is thermally treated for stability, after which the sample can be used as a capacitor.

Those skilled in the art will recognize, upon consideration of the above teachings, that the above exemplary embodiments may be implemented by a controller and may be based upon use of one or more programmed processors programmed with a suitable computer program. However, the disclosed embodiments could be implemented using hardware component equivalents such as special purpose hardware and/or dedicated processors. Similarly, general-purpose computers, microprocessor based computers, micro-controllers, optical computers, analog computers, dedicated processors, application specific circuits and/or dedicated hard wired logic may be used to construct alternative equivalent embodiments.

Moreover, it should be understood that control and cooperation of the above-described components may be provided using software instructions that may be stored in a tangible, non-transitory storage device such as a non-transitory computer readable storage device storing instructions which, when executed on one or more programmed processors, carry out he above-described method operations and resulting functionality. In this case, the term “non-transitory” is intended to preclude transmitted signals and propagating waves, but not storage devices that are erasable or dependent upon power sources to retain information.

Those skilled in the art will appreciate, upon consideration of the above teachings, that the program operations and processes and associated data used to implement certain of the embodiments described above can be implemented using disc storage as well as other forms of storage devices including, but not limited to non-transitory storage media (where non-transitory is intended only to preclude propagating signals and not signals which are transitory in that they are erased by removal of power or explicit acts of erasure) such as for example Read Only Memory (ROM) devices, Random Access Memory (RAM) devices, network memory devices, optical storage elements, magnetic storage elements, magneto-optical storage elements, flash memory, core memory and/or other equivalent volatile and non-volatile storage technologies without departing from certain embodiments. Such alternative storage devices should be considered equivalents.

1. A method for growing concentrically layered materials comprising:
forming patterned arrays of electrically conductive columns;
growing concentrically layered materials on the patterned arrays of electrically conductive columns, and
subsequently modifying the concentrically layered materials by immersion in a gaseous environment having compounds, molecules, or elements for implantation.

2. The method of claim 1, wherein at least one of the concentrically layered materials is removed after deposition so as to form a capacitor.

3. The method of claim 1, wherein the concentrically layered materials are grown as iron and then modified using a nitriding process to generate Fe₁₆N₂ iron nitride.

4. The method of claim 1, further comprising heating the modified concentrically layered materials to bring about specific phases in the sample.

5. The method of claim 1, wherein the process of growing comprises depositing metals via electroplating and then depositing metals or relevant magnetics via immersion is robotically automated.

6. The method of claim 1, wherein the layered materials form a magnetizable component.

7. An apparatus for growing concentrically layered materials comprising:
at least one vacuum chamber capable of controlling processing of samples for electroplating as well as gas phase deposition or implantation of materials, wherein the apparatus is used to sequentially grow and modify material films layer by layer.

8. The apparatus of claim 6, further comprising a robotic or automated controller.

9. The apparatus of claim 6, configured to grow composite materials.

10. The apparatus of claim 6, configured to generate composition gradients across a sample.

11. The apparatus of claim 6, configured to grow systems of two disparate conducting materials, selectively remove one of the disparate conducting materials, then replace the selectively removed material with an insulator so as to form arrays of capacitors.

12. The apparatus of claim 6, configured to generate magnetizable materials including one or more of the following: ferromagnetic layers, paramagnetic layers, superparamagnetic layers, or electropermanent magnet layers.
